(19) United States
(12) Patent Application Publication
(10) Pub. No.: US 2022/0120822 A1
(43) Pub. Date: Apr. 21, 2022

(54) SHORT-CIRCUIT DETECTION DEVICE AND SHORT-CIRCUIT DETECTION METHOD

(71) Applicant: Mitsubishi Electric Corporation, Tokyo (JP)

(72) Inventors: Yuji TAKIZAWA, Tokyo (JP); Haruyuki KOMETANI, Tokyo (JP); Atsushi YAMAMOTO, Tokyo (JP); Susumu MAEDA, Tokyo (JP); Nobuaki MUROKI, Tokyo (JP)

(73) Assignee: Mitsubishi Electric Corporation, Tokyo (JP)

(21) Appl. No.: 17/424,165

(22) PCT Filed: Mar. 12, 2019
(86) PCT No.: PCT/JP2019/010008

§ 371 Date: Jul. 20, 2021

(51) Int. Cl. G01R 31/52; G01R 31/72

(52) U.S. Cl. CPC G01R 31/52; G01R 31/72

(57) ABSTRACT

Provided is a short-circuit detection device configured to detect a short circuit of a field winding wound in a plurality of rotor slots in a rotor of a rotating electric machine, the short-circuit detection device including: a signal conversion unit configured to convert a detection signal in which a circumferential distribution of a magnetic flux of the rotor is detected into an energy equivalent signal corresponding to a circumferential distribution of magnetic energy of the rotor; and a short-circuit detection unit configured to detect a rotor slot in which the short circuit has occurred through use of the energy equivalent signal.

### TECHNICAL FIELD

The present invention relates to a short-circuit detection device and a short-circuit detection method for detecting a short circuit of a field winding in a rotor of a rotating electric machine.

### BACKGROUND ART

In Patent Literature 1, there is described a rotor winding abnormality detection device for a rotating electric machine. The rotor winding abnormality detection device includes a magnetic flux detection element and a determination device. The magnetic flux detection element is held in a stationary state and close to an outer peripheral surface of a rotor. The determination device is configured to determine whether or not a rotor winding has abnormality based on a pulsation signal waveform which is obtained from the magnetic flux detection element, and corresponds to a pulsation magnetic flux caused by a current of the rotor winding.

### CITATION LIST

### Patent Literature

[PTL 1] JP 58-005682 A

### SUMMARY OF INVENTION

### Technical Problem

In the above-mentioned rotor winding abnormality detection device, the magnetic flux detection element detects a field magnetic flux generated in a rotor slot. The field magnetic flux refers to a leakage magnetic flux caused between adjacent rotor slots. In addition to the field magnetic flux, a main magnetic flux interlinks with the magnetic flux detection element. The main magnetic flux is caused by an interaction between the above-mentioned field magnetic flux and an armature reaction magnetic flux generated from a multi-phase winding of a stator.

A magnitude and a phase of the main magnetic flux change depending on an operation condition of the rotating electric machine. Meanwhile, a magnitude and a phase of the field magnetic flux vary depending on a position of a rotor slot in which a short circuit of a field winding has occurred and the number of short-circuit turns in this rotor slot. That is, in some cases, the variation of the field magnetic flux may be relatively small with respect to the magnitude of the main magnetic flux, and an S/N ratio may be reduced, depending on the position of the rotor slot in which the short circuit of the field winding has occurred. Accordingly, in the above-mentioned rotor winding abnormality detection device, there has been a problem in that, in some cases, the rotor slot in which the short circuit of the field winding has occurred cannot be specified with high accuracy.

The present invention has been made to solve the above-mentioned problems, and has an object to provide a short-circuit detection device and a short-circuit detection method with which a rotor slot in which a short circuit of a field winding has occurred can be specified with higher accuracy.

### Solution to Problem

According to one embodiment of the present invention, there is provided a short-circuit detection device configured to detect a short circuit of a field winding wound in a plurality of rotor slots in a rotor of a rotating electric machine, the short-circuit detection device including: a signal conversion unit configured to convert a detection signal in which a circumferential distribution of a magnetic flux of the rotor is detected into an energy equivalent signal corresponding to a circumferential distribution of magnetic energy of the rotor; and a short-circuit detection unit configured to detect a rotor slot in which the short circuit has occurred through use of the energy equivalent signal.

According to one embodiment of the present invention, there is provided a short-circuit detection method for detecting a short circuit of a field winding wound in a plurality of rotor slots in a rotor of a rotating electric machine, the short-circuit detection method including: converting a detection signal in which a circumferential distribution of a magnetic flux of the rotor is detected into an energy equivalent signal corresponding to a circumferential distribution of magnetic energy of the rotor; and detecting a rotor slot in which the short circuit has occurred through use of the energy equivalent signal.

### Advantageous Effects of Invention

According to the present invention, the rotor slot in which the short circuit of the field winding has occurred can be specified with higher accuracy.

### BRIEF DESCRIPTION OF DRAWINGS

FIG. 1 is a block diagram for illustrating a configuration of a short-circuit detection device according to a first embodiment of the present invention.

FIG. 2 is a graph for showing a waveform of a search coil voltage signal in a case in which an operation condition of a turbine generator is Condition 1.

FIG. 3 is a graph for showing a waveform of a search coil voltage signal in a case in which the operation condition of the turbine generator is Condition 2.

FIG. 4 is a graph for showing a voltage waveform of a difference between a search coil voltage signal in a short-circuit state and a search coil voltage signal in a sound state in the case in which the operation condition of the turbine generator is Condition 1.

FIG. 5 is a graph for showing a voltage waveform of a difference between the search coil voltage signal in the short-circuit state and the search coil voltage signal in the sound state in the case in which the operation condition of the turbine generator is Condition 2.

FIG. 6 is a graph for showing a waveform of an energy equivalent signal in the case in which the operation condition of the turbine generator is Condition 1.

FIG. 7 is a graph for showing a waveform of an energy equivalent signal in the case in which the operation condition of the turbine generator is Condition 2.

FIG. 8 is a graph for showing a waveform of a difference between an energy equivalent signal in the short-circuit state and an energy equivalent signal in the sound state in the case in which the operation condition of the turbine generator is Condition 1.

FIG. 9 is a graph for showing a waveform of a difference between the energy equivalent signal in the short-circuit state and the energy equivalent signal in the sound state in the case in which the operation condition of the turbine generator is Condition 2.

FIG. 10 is a flow chart for illustrating a flow of short-circuit detection processing in the short-circuit detection device according to the first embodiment of the present invention.

FIG. 11 is a block diagram for illustrating a configuration of a short-circuit detection device according to a second embodiment of the present invention.

FIG. 12 is a flow chart for illustrating a flow of short-circuit detection processing in the short-circuit detection device according to the second embodiment of the present invention.

FIG. 13 is a flow chart for illustrating a flow of short-circuit detection processing in a short-circuit detection device according to a third embodiment of the present invention.

FIG. 14 is a flow chart for illustrating a flow of short-circuit detection processing in a short-circuit detection device according to a fourth embodiment of the present invention.

### DESCRIPTION OF EMBODIMENTS

### First Embodiment

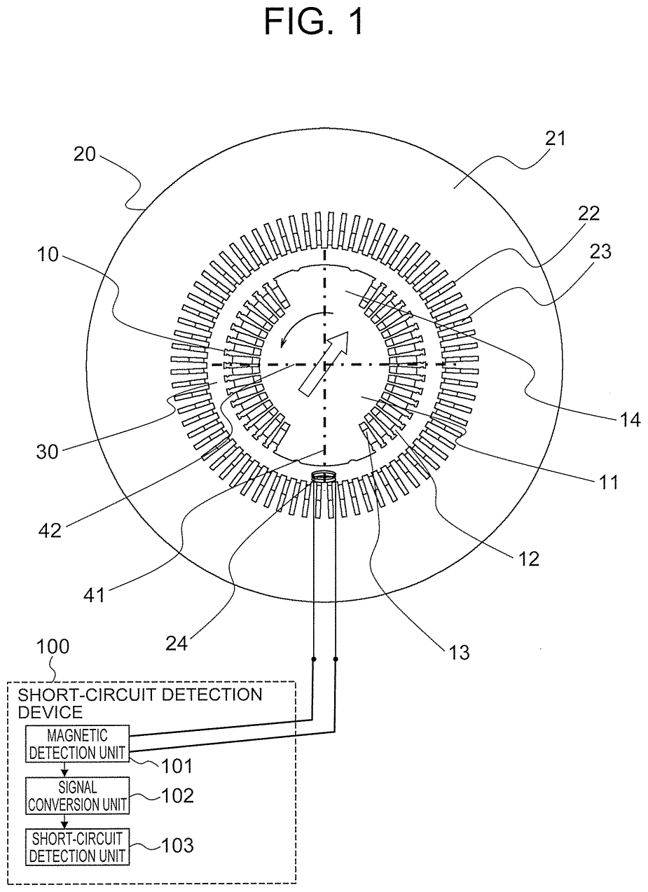

A short-circuit detection device and a short-circuit detection method according to a first embodiment of the present invention are described. FIG. 1 is a block diagram for illustrating a configuration of a short-circuit detection device according to a first embodiment of the present invention. In FIG. 1, a configuration as viewed along an axial direction of a rotating electric machine being a detection target of the short-circuit detection device is illustrated together. In this embodiment, a turbine generator is exemplified as the rotating electric machine.

First, the configuration of the turbine generator is described. As illustrated in FIG. 1, the turbine generator includes a rotor 10 and a stator 20. The rotor 10 is provided so as to be freely rotatable. The stator 20 is provided on an outer side of the rotor 10. An outer peripheral portion of the rotor 10 and an inner peripheral portion of the stator 20 are opposed to each other via an air gap 30. In a rotor core 11 of the rotor 10, a plurality of rotor slots 12 are formed. A series-connected field winding 13 is wound in the plurality of rotor slots 12. The field winding 13 is subjected to DC excitation from an external power supply so that the rotor core 11 is magnetized into two poles. In this manner, in the rotor core 11, two magnetic poles 14 are formed. In FIG. 1, a magnetic pole center direction 41 and an inter-pole center direction 42 are illustrated. The magnetic pole center direction 41 passes through a center axis of the rotor 10 and a center of each magnetic pole 14. The inter-pole center direction 42 passes through the center axis of the rotor 10 and a center between the two magnetic poles 14 adjacent to each other in a circumferential direction.

In a stator core 21 of the stator 20, a plurality of stator slots 22 are formed. A multi-phase winding 23 is wound in the plurality of stator slots 22. The multi-phase winding 23 is subjected to AC excitation so that a rotation magnetic field is caused in the air gap 30. The turbine generator illustrated in FIG. 1 is a two-pole generator having thirty-two rotor slots 12 and seventy-two stator slots 22. The thick arrow of FIG. 1 indicates a direction of a main magnetic flux in a case in which the turbine generator is operated at a rated load. Further, the arrow in the counterclockwise direction of FIG. 1 indicates a rotating direction of the rotor 10.

In a part of the stator 20 facing the air gap 30, a search coil 24 is provided as a magnetic detector configured to detect a magnetic flux of the rotor 10 in the air gap 30. The main magnetic flux and a field magnetic flux of the rotor 10 interlink with the search coil 24. Accordingly, a voltage corresponding to the magnetic fluxes interlinking with the search coil 24 is generated between terminals at both ends of the search coil 24. The magnetic fluxes interlinking with the search coil 24 vary along with the rotation of the rotor 10. Accordingly, along with the rotation of the rotor 10, a search coil voltage signal corresponding to variations of a magnetic flux density along a circumferential direction of the rotor 10 is output from the search coil 24. The search coil voltage signal serves as a detection signal in which a circumferential distribution of a magnetic flux of the rotor 10 is detected. In this embodiment, the search coil 24 configured to detect a magnetic flux density in a radial direction of the rotor 10 in the air gap 30 is used, but a search coil configured to detect a magnetic flux density in the circumferential direction of the rotor 10 in the air gap 30 may be used instead.

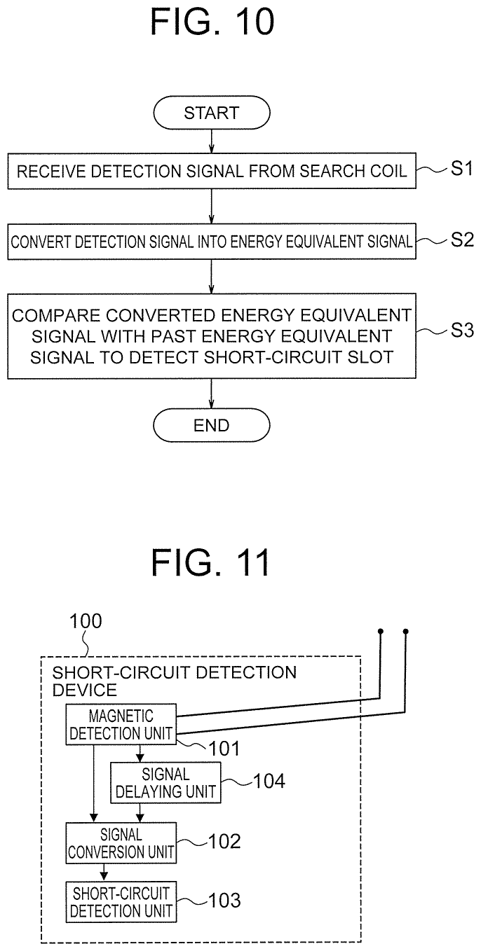

A short-circuit detection device 100 is connected to the search coil 24 as required. The short-circuit detection device 100 includes, as a hardware configuration, a processor, a storage device, an input/output interface circuit, and the like. Further, the short-circuit detection device 100 includes a magnetic detection unit 101, a signal conversion unit 102, and a short-circuit detection unit 103. The magnetic detection unit 101 is configured to receive a search coil voltage signal from the search coil 24. The signal conversion unit 102 is configured to convert the search coil voltage signal received by the magnetic detection unit 101 into an energy equivalent signal to be described later. The short-circuit detection unit 103 is configured to detect the rotor slot 12 in which a short circuit of the field winding 13 has occurred through use of the energy equivalent signal. The rotor slot 12 in which a short circuit of the field winding 13 has occurred is hereinafter sometimes referred to as “short-circuit slot.” The magnetic detection unit 101, the signal conversion unit 102, and the short-circuit detection unit 103 are functional blocks to be implemented by the processor executing programs stored in the storage device. For example, the magnetic detection unit 101 is a functional block corresponding to Step S1 of FIG. 10 to be referred to later. The signal conversion unit 102 is a functional block corresponding to Step S2 of FIG. 10. The short-circuit detection unit 103 is a functional block corresponding to Step S3 of FIG. 10.

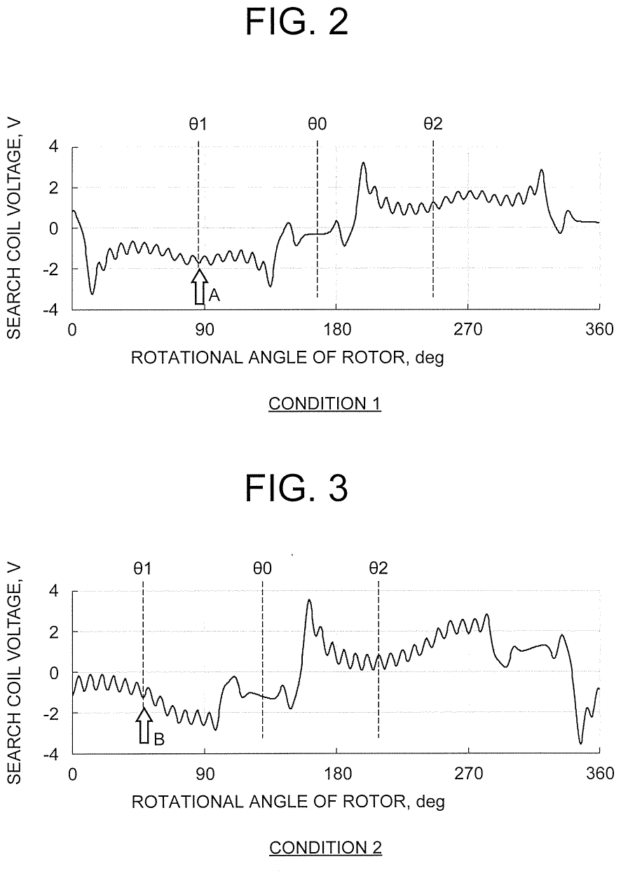

Next, as a premise of this embodiment, description is given of a short-circuit detection method using the search coil voltage signal as it is. FIG. 2 and FIG. 3 are each a graph for showing a waveform of a search coil voltage signal obtained through electromagnetic field analysis in each of two operation conditions simulating an actual operation of the turbine generator. The horizontal axis of FIG. 2 and FIG. 3 represents a rotational angle (deg) of the rotor 10, and the vertical axis of FIG. 2 and FIG. 3 represents a search coil voltage (V). Here, it is assumed that a short circuit corresponding to one turn of the field winding 13 has occurred in the seventh rotor slot 12 from the field magnetic pole center. In FIG. 2 and FIG. 3, a rotational angle θ0 corresponds to a direction of a magnetic pole center on a side on which the short circuit of the field winding 13 has occurred. As shown in FIG. 2 and FIG. 3, the waveform of the search coil voltage signal of each magnetic pole is almost inversion symmetric. Further, in FIG. 2 and FIG. 3, rotational angles θ1 and θ2 correspond to positions of short-circuit slots. The rotational angle θ1 corresponds to a position of, among the short-circuit slots, a short-circuit slot on a side farther from the main magnetic flux direction with respect to a center axis of the rotor 10 serving as a starting point. That is, the rotational angle θ1 corresponds to a position of, among the short-circuit slots, a short-circuit slot on a forward side in the rotating direction of the rotor 10. The rotational angle θ2 corresponds to a position of, among the short-circuit slots, a short-circuit slot on a side closer to the main magnetic flux direction with respect to the center axis of the rotor 10 serving as a starting point. That is, the rotational angle θ2 corresponds to a position of, among the short-circuit slots, a short-circuit slot on a backward side in the rotating direction of the rotor 10.

FIG. 2 shows a waveform of a search coil voltage signal in a case in which the operation condition of the turbine generator is Condition 1. In FIG. 2, the rotational angle θ0 corresponding to the magnetic pole center direction is about 170°. In FIG. 2, the position of the short-circuit slot on the side farther from the main magnetic flux direction is indicated by the arrow A. As shown in FIG. 2, in the short-circuit slot, an absolute value of a voltage is reduced due to reduction of a magnetomotive force by an amount corresponding to the number of short-circuit turns.

FIG. 3 shows a waveform of a search coil voltage signal in a case in which the operation condition of the turbine generator is Condition 2 different from Condition 1. In FIG. 3, the rotational angle θ0 corresponding to the magnetic pole center direction is about 130°. In FIG. 3, the position of the short-circuit slot on the side farther from the main magnetic flux direction is indicated by the arrow B. As shown in FIG. 3, in the short-circuit slot, an absolute value of a voltage is reduced due to reduction of a magnetomotive force by an amount corresponding to the number of short-circuit turns.

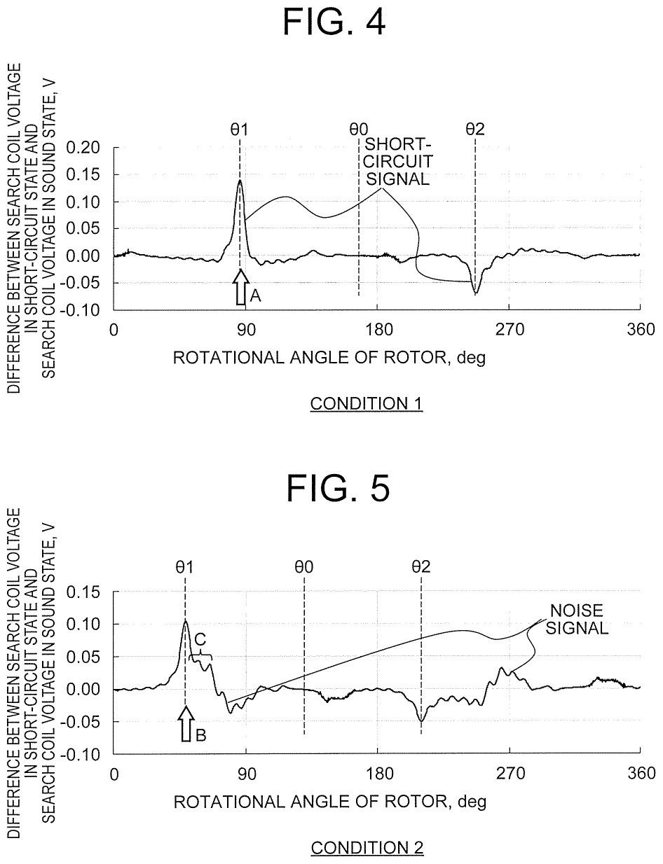

FIG. 4 and FIG. 5 are each a graph for showing a voltage waveform obtained by calculating a difference between a search coil voltage signal in a short-circuit state in which a short circuit of the field winding 13 has occurred, and a search coil voltage signal in a sound state in which no short circuit of the field winding 13 has occurred. The horizontal axis of FIG. 4 and FIG. 5 represents the rotational angle (deg) of the rotor 10, and the vertical axis of FIG. 4 and FIG. 5 represents a difference (V) between a search coil voltage in the short-circuit state and a search coil voltage in the sound state.

FIG. 4 shows a voltage waveform obtained by calculating the difference between the search coil voltage signal in the short-circuit state and the search coil voltage signal in the sound state in the case in which the operation condition of the turbine generator is Condition 1. In the voltage waveform shown in FIG. 4, a peak indicating the occurrence of the short circuit, that is, a short-circuit signal, appears at positions of the rotational angles θ1 and θ2. In the voltage waveform shown in FIG. 4, a half width of the short-circuit signal is relatively narrow. As a result, the short-circuit signal and a noise signal other than the short-circuit signal can be distinguished from each other, and hence the position of the short-circuit slot can be detected.

FIG. 5 shows a voltage waveform of a difference between the search coil voltage signal in the short-circuit state and the search coil voltage signal in the sound state in the case in which the operation condition of the turbine generator is Condition 2. Also in the voltage waveform shown in FIG. 5, the short-circuit signal appears at the positions of the rotational angles θ1 and θ2. However, in the voltage waveform shown in FIG. 5, the noise signal other than the short-circuit signal is relatively large, and hence the half width of the short-circuit signal is increased. In addition, the short-circuit signal has a wide foot. Thus, the short-circuit signal extends across a plurality of slots. Specifically, the short-circuit signal at the position of the arrow B extends across not only the short-circuit slot, but also two sound slots in a range C adjacent to the short-circuit slot. Accordingly, in the case in which the operation condition of the turbine generator is Condition 2, it is difficult to detect the position of the short-circuit slot with high accuracy, and there is a fear in that it may be erroneously determined that the short circuit of the field winding 13 has occurred in three rotor slots 12. Further, in this case, in order to detect the position of the short-circuit slot with high accuracy, it is required to acquire the search coil voltage signal again under a state in which the operation condition of the turbine generator is changed to, for example, Condition 1. Accordingly, when the search coil voltage signal is used as it is, in some cases, it becomes difficult to rapidly detect the position of the short-circuit slot with high accuracy.

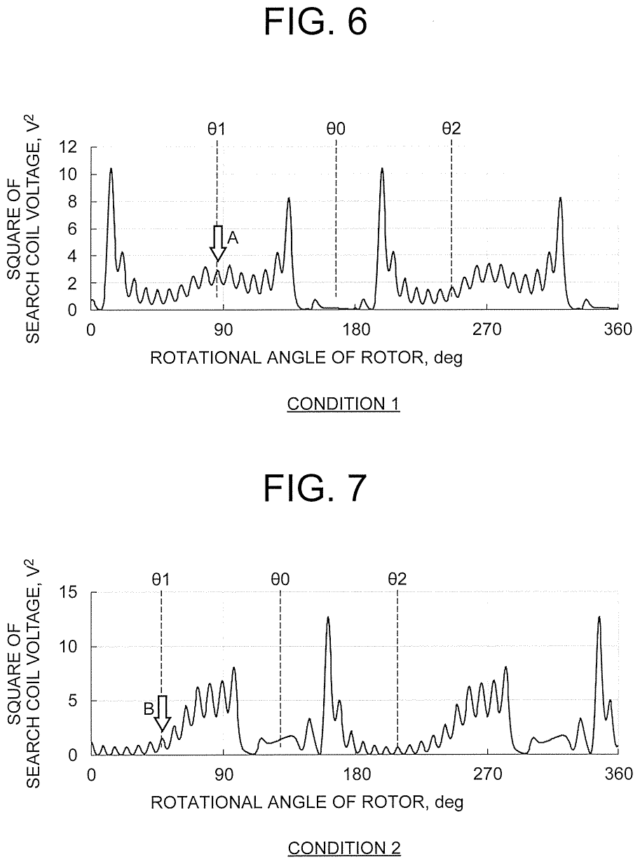

Next, description is given of a short-circuit detection method using the energy equivalent signal. FIG. 6 is a graph for showing a waveform of an energy equivalent signal in the case in which the operation condition of the turbine generator is Condition 1. The energy equivalent signal shown in FIG. 6 is converted from the search coil voltage signal shown in FIG. 2. FIG. 7 is a graph for showing a waveform of an energy equivalent signal in the case in which the operation condition of the turbine generator is Condition 2. The energy equivalent signal shown in FIG. 7 is converted from the search coil voltage signal shown in FIG. 3. The energy equivalent signal is a signal corresponding to magnetic energy of the rotor 10, and is converted from the search coil voltage signal through use of an energy equivalent value obtained by squaring each instantaneous value of the search coil voltage signal. The horizontal axis of FIG. 6 and FIG. 7 represents the rotational angle (deg) of the rotor 10, and the vertical axis of FIG. 6 and FIG. 7 represents the square (V²) of the search coil voltage.

As shown in FIG. 6 and FIG. 7, with the instantaneous value of the search coil voltage signal being squared, all values of the energy equivalent signal are 0 or more. Along therewith, the whole change of the magnetic flux amount in the air gap 30 caused by the short circuit of the field winding 13 can be grasped as reduction of a magnetomotive force of the field winding 13. Further, variation components of harmonics corresponding to the respective rotor slots 12 in the waveform shown in FIG. 6 each have a narrower half width as compared to the waveform shown in FIG. 2, based on the double-angle formulas of trigonometric functions. Similarly, variation components of harmonics corresponding to the respective rotor slots 12 in the waveform shown in FIG. 7 each have a narrower half width as compared to the waveform shown in FIG. 3, based on the double-angle formulas of trigonometric functions. That is, the waveforms shown in FIG. 6 and FIG. 7 are, as compared to the waveforms shown in FIG. 2 and FIG. 3, waveforms in which variations are sharply emphasized. Accordingly, when the short circuit of the field winding 13 is detected through use of the energy equivalent signal, a spatial resolution for specifying the short-circuit slot is improved.

Now, description is given of a principle of how the spatial resolution is improved through use of the energy equivalent signal. Variations of the search coil voltage signal are caused by the short circuit of the field winding 13 due to mainly decrease of odd-order components or increase of even-order components, and are caused in a first-order fundamental component and high-order harmonic components. For the sake of simplification, when an n-th order component being one component of the search coil voltage signal is represented by cos(ne), the squared value being the energy equivalent value is (cos(nθ))². The value of (cos(nθ))² is the same as “0.5+0.5×cos(2nθ)” based on the double-angle formulas of trigonometric functions. That is, it is understood that, when the search coil voltage signal having an n-th order spatial resolution is converted into the energy equivalent value, the n-th order is doubled to achieve a 2n-th order spatial resolution.

Further, “0.5+0.5×cos(2nθ)” is 0 or more, and hence the value in the vertical axis of each of FIG. 6 and FIG. 7 is also 0 or more. Physically, when a short circuit of the field winding 13 occurs in a certain rotor slot 12, the number of sound turns of the field winding 13 is reduced in the short-circuit slot, and hence the magnetomotive force of the field winding 13 is always reduced. The reduction of the magnetomotive force is caused in a phase corresponding to the short-circuit slot.

Meanwhile, the search coil voltage signal has both positive and negative values as expressed as cos(nθ). This can be confirmed even from the fact that the search coil voltage has both positive and negative values in the graphs shown in FIG. 2 and FIG. 3. As shown in FIG. 4 and FIG. 5, the short-circuit signal appears in both of positive and negative directions. Accordingly, when a component of a noise signal other than the short-circuit signal is large as in Condition 2, the short-circuit signal may be superimposed with the noise. Thus, the short circuit may not be detected, or the noise signal may be erroneously detected as the short-circuit signal.

In contrast, in this embodiment, the short-circuit slot is detected through use of the energy equivalent signal corresponding to the magnetic energy of the rotor 10. For example, a difference obtained by subtracting the energy equivalent signal in the sound state from the energy equivalent signal in the short-circuit state always has a negative value at a phase corresponding to the short-circuit slot due to the reduction of the magnetomotive force, that is, the reduction of the magnetic energy. Accordingly, when a threshold value is set to a negative value, the short-circuit slot can be detected with high accuracy regardless of the variations on the positive value side caused by the noise in the above-mentioned difference. Further, the reduction of the magnetic flux density caused by the short circuit is grasped as the reduction of the magnetic energy regardless of a rate of the decrease of the odd-order components or the increase of the even-order components in the search coil voltage signal, and hence the short-circuit slot can be detected with high accuracy.

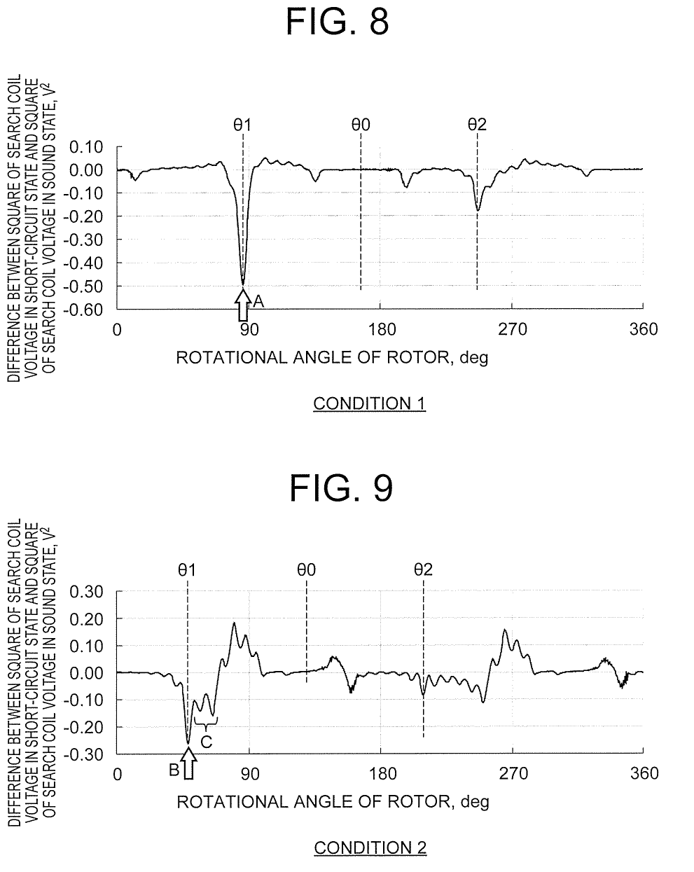

FIG. 8 is a graph for showing a waveform of a difference between the energy equivalent signal in the short-circuit state and the energy equivalent signal in the sound state in the case in which the operation condition of the turbine generator is Condition 1. FIG. 9 is a graph for showing a waveform of a difference between the energy equivalent signal in the short-circuit state and the energy equivalent signal in the sound state in the case in which the operation condition of the turbine generator is Condition 2. The horizontal axis of FIG. 8 and FIG. 9 represents the rotational angle (deg) of the rotor 10, and the vertical axis of FIG. 8 and FIG. 9 represents a difference (V²) between the square of the search coil voltage in the short-circuit state and the square of the search coil voltage in the sound state.

In the waveforms shown in FIG. 8 and FIG. 9, it can be confirmed that the short-circuit signals at both of the positions of the rotational angles 81 and 82 appear on the negative value side so as to reflect the reduction of the magnetomotive force, that is, the reduction of the magnetic energy. Further, it is understood that, in the waveform shown in FIG. 8, as compared to the waveform shown in FIG. 4, the half width of the short-circuit signal is narrower. In this manner, at least the position of the short-circuit slot indicated by the arrow A can be specified with high accuracy. Further, it is understood that, in the waveform shown in FIG. 9, as compared to the waveform shown in FIG. 5, the half width of the short-circuit signal is narrower, and further peaks for the three slots can be clearly distinguished. In this manner, at least the position of the short-circuit slot indicated by the arrow B can be specified with high accuracy.

FIG. 10 is a flow chart for illustrating a flow of short-circuit detection processing in the short-circuit detection device 100 according to this embodiment. The processing illustrated in FIG. 10 is performed by the processor of the short-circuit detection device 100 executing the program stored in the storage device of the short-circuit detection device 100. As illustrated in FIG. 10, first, the short-circuit detection device 100 receives a search coil voltage signal from the search coil 24 as a detection signal (Step S1).

Next, the short-circuit detection device 100 converts the received search coil voltage signal into an energy equivalent signal through use of a value obtained by squaring an instantaneous value of the received search coil voltage signal (Step S2). The energy equivalent signal may be obtained through conversion by using the value obtained by squaring the instantaneous value of the search coil voltage signal as it is, or may be obtained through conversion by adding or subtracting any value to or from the value obtained by squaring the instantaneous value of the search coil voltage signal. Further, the energy equivalent signal may be obtained through conversion by using, in place of the value obtained by squaring the instantaneous value of the search coil voltage signal, a value obtained by squaring an average value of the search coil voltage signal in each sampling time which is sufficiently smaller than a pitch of the rotor slots 12.

Next, the short-circuit detection device 100 compares the energy equivalent signal converted in Step S2 with a past energy equivalent signal which is the energy equivalent signal in the sound state, to thereby detect the short-circuit slot (Step S3). In this case, the short-circuit detection device 100 receives the search coil voltage signal from the search coil 24 in advance when no short circuit of the field winding 13 occurs, and stores the energy equivalent signal converted from the search coil voltage signal as the past energy equivalent signal in the storage device. For example, the short-circuit detection device 100 determines, as a short-circuit signal, a peak of falling below the threshold value set to a negative value in the waveform of the difference between the energy equivalent signal converted in Step S2 and the past energy equivalent signal, to thereby specify the short-circuit slot based on the position of the short-circuit signal. In this case, the past energy equivalent signal may be temporarily continuous or non-continuous from the current energy equivalent signal.

After that, the short-circuit detection device 100 notifies a notification unit (not shown) of whether or not the short circuit has occurred as required. Further, when a short circuit of the field winding 13 has occurred, the short-circuit detection device 100 notifies the notification unit of the position of the short-circuit slot as required.

As described above, the short-circuit detection device 100 according to this embodiment is a short-circuit detection device configured to detect a short circuit of the field winding 13 wound in the plurality of rotor slots 12 in the rotor 10 of the turbine generator. The short-circuit detection device 100 includes: the signal conversion unit 102 configured to convert a search coil voltage signal in which a circumferential distribution of a magnetic flux of the rotor 10 is detected into an energy equivalent signal corresponding to a circumferential distribution of magnetic energy of the rotor 10; and the short-circuit detection unit 103 configured to detect the rotor slot 12 in which the short circuit of the field winding 13 has occurred through use of the energy equivalent signal. In this case, the turbine generator is an example of the rotating electric machine. The search coil voltage signal is an example of the detection signal.

With this configuration, through use of the energy equivalent signal, the short circuit of the field winding 13 can be detected at a high spatial resolution. Accordingly, the rotor slot 12 in which a short circuit has occurred can be specified with higher accuracy regardless of the operation condition of the turbine generator, the position of the rotor slot 12 in which the short circuit has occurred, the installation position of the search coil 24, and the like.

Further, in the short-circuit detection device 100 according to this embodiment, the signal conversion unit 102 may be configured to convert the search coil voltage signal into the energy equivalent signal through use of a value obtained by squaring an instantaneous value of the search coil voltage signal or a value obtained by squaring an average value in each sampling time of the search coil voltage signal. With this configuration, the short circuit of the field winding 13 can be detected at a high spatial resolution, and hence the rotor slot 12 in which the short circuit of the field winding 13 has occurred can be specified with higher accuracy.

Further, in the short-circuit detection device 100 according to this embodiment, the short-circuit detection unit 103 may be configured to compare the energy equivalent signal converted from the current search coil voltage signal with the energy equivalent signal converted from the past search coil voltage signal, to thereby detect the rotor slot 12 in which the short circuit has occurred. With this configuration, through waveform comparison in the time direction, the rotor slot 12 in which the short circuit of the field winding 13 has occurred can be specified.

Further, the short-circuit detection method according to this embodiment is a short-circuit detection method for detecting a short circuit of the field winding 13 wound in the plurality of rotor slots 12 in the rotor 10 of the turbine generator, the short-circuit detection method including: converting a detection signal in which a circumferential distribution of a magnetic flux of the rotor 10 is detected into an energy equivalent signal corresponding to a circumferential distribution of magnetic energy of the rotor 10; and detecting the rotor slot 12 in which the short circuit has occurred through use of the energy equivalent signal.

With this configuration, through use of the energy equivalent signal, the short circuit of the field winding 13 can be detected at a high spatial resolution, and hence the rotor slot 12 in which the short circuit of the field winding 13 has occurred can be specified with higher accuracy.

### Second Embodiment

A short-circuit detection device and a short-circuit detection method according to a second embodiment of the present invention are described. FIG. 11 is a block diagram for illustrating a configuration of the short-circuit detection device 100 according to this embodiment. Components having the same functions and actions as those of the first embodiment are denoted by the same reference symbols, and description thereof is omitted here. In this embodiment, the rotation of the rotor 10 is used to detect the short-circuit slot through use of a search coil voltage signal of a short-circuit magnetic pole in which the short circuit of the field winding 13 has occurred and a search coil voltage signal of a sound magnetic pole in which no short circuit has occurred.

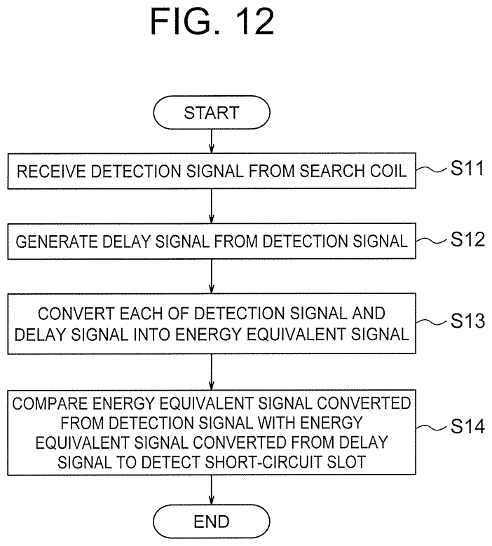

As illustrated in FIG. 11, the short-circuit detection device 100 includes a signal delaying unit 104 in addition to the magnetic detection unit 101, the signal conversion unit 102, and the short-circuit detection unit 103. The signal delaying unit 104 is configured to generate a delay signal by delaying the phase of the search coil voltage signal received by the magnetic detection unit 101 by 180° in an electrical angle. The signal delaying unit 104 is a functional block to be implemented by the processor executing the program stored in the storage device. For example, the signal delaying unit 104 is a functional block corresponding to Step S13 of FIG. 12 to be referred to later.

FIG. 12 is a flow chart for illustrating a flow of short-circuit detection processing in the short-circuit detection device 100 according to this embodiment. The processing illustrated in FIG. 12 is performed by the processor of the short-circuit detection device 100 executing the program stored in the storage device of the short-circuit detection device 100. As illustrated in FIG. 12, first, the short-circuit detection device 100 receives a search coil voltage signal from the search coil 24 as a detection signal (Step S11).

Next, the short-circuit detection device 100 generates the above-mentioned delay signal from the received search coil voltage signal (Step S12).

Next, the short-circuit detection device 100 converts each of the search coil voltage signal received in Step S11 and the delay signal generated in Step S12 into an energy equivalent signal by a method similar to that in the first embodiment (Step S13). In this manner, two energy equivalent signals different from each other by a phase of 180° in an electrical angle are generated.

Next, the short-circuit detection device 100 compares the energy equivalent signal converted from the search coil voltage signal and the energy equivalent signal converted from the delay signal, to thereby detect the short-circuit slot (Step S14). For example, the short-circuit detection device 100 specifies the short-circuit slot based on the waveform of the difference between the energy equivalent signal converted from the search coil voltage signal and the energy equivalent signal converted from the delay signal. In this manner, through comparison between the energy equivalent signal of the short-circuit magnetic pole in which the short circuit of the field winding 13 has occurred and the energy equivalent signal of the sound magnetic pole in which no short circuit has occurred, the short-circuit slot can be detected.

As described above, the short-circuit detection device 100 according to this embodiment further includes the signal delaying unit 104 configured to generate the delay signal by delaying the phase of the search coil voltage signal by 180° in the electrical angle. The signal conversion unit 102 is configured to convert the delay signal into the energy equivalent signal. The short-circuit detection unit 103 is configured to compare the energy equivalent signal converted from the search coil voltage signal with the energy equivalent signal converted from the delay signal, to thereby detect the rotor slot 12 in which the short circuit has occurred. With this configuration, through waveform comparison in the spatial direction, the rotor slot 12 in which the short circuit of the field winding 13 has occurred can be specified.

### Third Embodiment

A short-circuit detection device and a short-circuit detection method according to an embodiment of the present invention are described. In this embodiment, a plurality of search coils 24 are provided to the stator 20 of the turbine generator. The plurality of search coils 24 are arranged at positions different from each other by a phase of 180° or more in an electrical angle. As an example, two search coils 24 are arranged at positions different from each other by a phase of 180° in an electrical angle. In this manner, the magnetic detection unit 101 of the short-circuit detection device 100 receives a search coil voltage signal of a short-circuit magnetic pole in which the short circuit of the field winding 13 has occurred and a search coil voltage signal of a sound magnetic pole in which no short circuit has occurred.

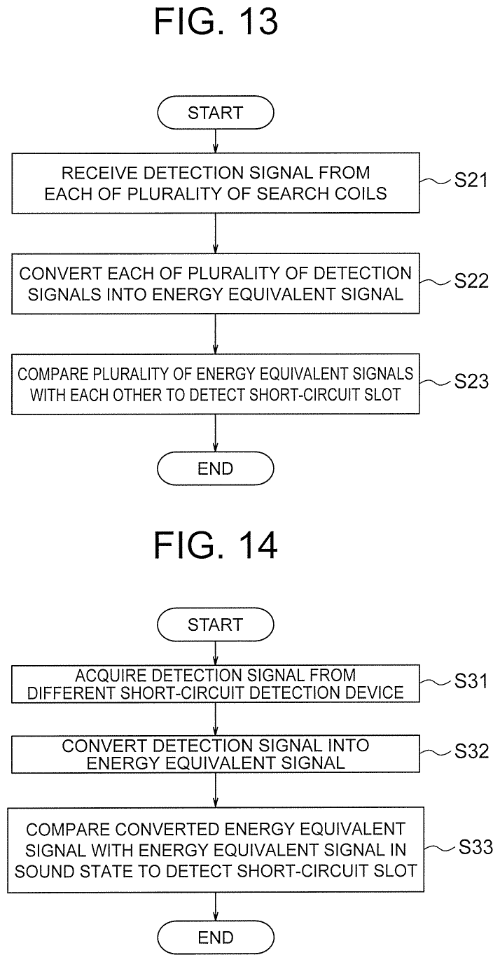

FIG. 13 is a flow chart for illustrating a flow of short-circuit detection processing in the short-circuit detection device 100 according to this embodiment. The processing illustrated in FIG. 13 is performed by the processor of the short-circuit detection device 100 executing the program stored in the storage device of the short-circuit detection device 100. As illustrated in FIG. 13, first, the short-circuit detection device 100 receives a search coil voltage signal from each of the plurality of search coils 24 as a detection signal (Step S21).

Next, the short-circuit detection device 100 converts each of the received plurality of search coil voltage signals into an energy equivalent signal (Step S22).

Next, the short-circuit detection device 100 compares the plurality of energy equivalent signals with each other, to thereby detect the short-circuit slot (Step S23). In this manner, through comparison between the energy equivalent signal of the short-circuit magnetic pole in which the short circuit of the field winding 13 has occurred and the energy equivalent signal of the sound magnetic pole in which no short circuit has occurred, the short-circuit slot can be detected.

As described above, in the short-circuit detection device 100 according to this embodiment, the signal conversion unit 102 is configured to convert the detection signals detected at a plurality of positions different from each other by a phase of 180° or more in an electrical angle into the energy equivalent signals. The short-circuit detection unit 103 is configured to compare the energy equivalent signals with each other, to thereby detect the rotor slot 12 in which the short circuit has occurred. With this configuration, through waveform comparison in the spatial direction, the rotor slot 12 in which the short circuit of the field winding 13 has occurred can be specified.

This embodiment can be executed in combination with the second embodiment. In this case, the rotation of the rotor 10 is used to generate the energy equivalent signal of the short-circuit magnetic pole in which the short circuit of the field winding 13 has occurred and the energy equivalent signal of the sound magnetic pole in which no short circuit has occurred, based on the search coil voltage signal from one search coil 24. Those energy equivalent signals are compared with each other, to thereby detect the short-circuit slot based on the search coil voltage signal from the one search coil 24. Further, the short-circuit slot is detected by a similar method also based on the search coil voltage signal from another search coil 24. Those detection results are collated to finally specify the short-circuit slot. As described above, when this embodiment and the second embodiment are executed in combination, erroneous detection of a short circuit and overlooking of a short circuit due to failure or the like can be avoided.

### Fourth Embodiment

A short-circuit detection device and a short-circuit detection method according to a fourth embodiment of the present invention are described. In this embodiment, a short-circuit detection device different from the short-circuit detection device 100 is used to detect that a short circuit has occurred in the field winding 13, and then the short-circuit detection device 100 is used to specify the short-circuit slot.

FIG. 14 is a flow chart for illustrating a flow of short-circuit detection processing in the short-circuit detection device 100 according to this embodiment. The processing illustrated in FIG. 14 is performed by the processor of the short-circuit detection device 100 executing the program stored in the storage device of the short-circuit detection device 100. In this case, it is assumed that the fact itself that the short circuit has occurred in the field winding 13 has been already detected by the above-mentioned different short-circuit detection device. Further, it is assumed that the above-mentioned different short-circuit detection device is configured to detect the short circuit of the field winding 13 through use of the search coil voltage signal as it is without converting the search coil voltage signal.

As illustrated in FIG. 14, first, the short-circuit detection device 100 acquires the search coil voltage signal from the above-mentioned different short-circuit detection device as the detection signal (Step S31).

Next, the short-circuit detection device 100 converts the acquired search coil voltage signal into an energy equivalent signal (Step S32).

Next, the short-circuit detection device 100 compares the energy equivalent signal converted in Step S32 with an energy equivalent signal in the sound state, to thereby detect the short-circuit slot (Step S33). The energy equivalent signal in the sound state is, for example, converted from the search coil voltage signal in the sound state acquired from the above-mentioned different short-circuit detection device, and is stored in the storage device.

As described above, in the short-circuit detection device 100 according to this embodiment, the search coil voltage signal is to be acquired from a device different from the short-circuit detection device 100. With this configuration, the existing short-circuit detection device can be used as it is. Further, when it is difficult to specify the short-circuit slot with the existing short-circuit detection device, the short-circuit detection device 100 according to this embodiment can be used to specify the short-circuit slot with higher accuracy.

The present invention is not limited to the above-mentioned embodiments, and various modifications can be made thereto. For example, in the above-mentioned embodiments, the search coil 24 is given as an example of the magnetic detector configured to detect the magnetic flux of the rotor 10, but the present invention is not limited thereto. The magnetic detector may be a magnetic sensor, for example, a Hall element, configured to measure a magnetic flux density through use of a Hall effect, or may be a magnetic sensor configured to measure a magnetic flux density through use of a magneto-resistive effect, for example, a giant magneto-resistive effect (GMR).

Further, in the above-mentioned embodiments, as the detection signal of the circumferential distribution of the magnetic flux of the rotor 10, the search coil voltage signal output from the search coil 24 is given as an example, but the detection signal may be a voltage signal output from a semiconductor element, or may be a current signal.

Further, in the above-mentioned embodiments, when the search coil voltage signal is converted into the energy equivalent signal, the value obtained by squaring the instantaneous value of the search coil voltage signal or the value obtained by squaring the average value in each sampling time of the search coil voltage signal is used, but the present invention is not limited thereto. In place of the above-mentioned instantaneous value or the above-mentioned average value, an effective value of the search coil voltage signal may be used. Further, instead of the squaring, mathematical processing which always allows a calculation result to be 0 or more as in the squaring may be performed. Even when such mathematical processing is performed to increase a measurement frequency to increase the spatial resolution, effects similar to those in the present invention can be obtained.

Further, regardless of whether or not the short circuit of the field winding 13 has occurred, two energy equivalent signals may be acquired continuously in time or at a time interval, and the two energy equivalent signals may be compared with each other to detect the short-circuit slot.

The first to fourth embodiments described above can be carried out in various combinations.

### REFERENCE SIGNS LIST

10 rotor, 11 rotor core, 12 rotor slot, 13 field winding, 14 magnetic pole, 20 stator, 21 stator core, 22 stator slot, 23 multi-phase winding, 24 search coil, 30 air gap, 41 magnetic pole center direction, 42 inter-pole center direction, 100 short-circuit detection device, 101 magnetic detection unit, 102 signal conversion unit, 103 short-circuit detection unit, 104 signal delaying unit

1. A short-circuit detection device configured to detect a short circuit of a field winding wound in a plurality of rotor slots in a rotor of a rotating electric machine, the short-circuit detection device comprising:
signal conversion circuitry configured to convert a detection signal in which a circumferential distribution of a magnetic flux of the rotor is detected into an energy equivalent signal corresponding to a circumferential distribution of magnetic energy of the rotor; and
short-circuit detection circuitry configured to detect a rotor slot in which the short circuit has occurred through use of the energy equivalent signal.

2. The short-circuit detection device according to claim 1, wherein the signal conversion circuitry is configured to convert the detection signal into the energy equivalent signal through use of a value obtained by squaring an instantaneous value of the detection signal or a value obtained by squaring an average value in each sampling time of the detection signal.

3. The short-circuit detection device according to claim 1, wherein the short-circuit detection circuitry is configured to compare the energy equivalent signal converted from a current detection signal with the energy equivalent signal converted from a past detection signal, to thereby detect the rotor slot in which the short circuit has occurred.

4. The short-circuit detection device according to claim 1, further comprising a signal delaying circuitry configured to generate a delay signal by delaying a phase of the detection signal by 180° in an electrical angle,
wherein the signal conversion circuitry is configured to convert the delay signal into the energy equivalent signal, and
wherein the short-circuit detection circuitry is configured to compare the energy equivalent signal converted from the detection signal with the energy equivalent signal converted from the delay signal, to thereby detect the rotor slot in which the short circuit has occurred.

5. The short-circuit detection device according to claim 1,
wherein the signal conversion circuitry is configured to convert the detection signals detected at respective positions different from each other by a phase of 180° or more in an electrical angle into the energy equivalent signals, and
wherein the short-circuit detection circuitry is configured to compare the energy equivalent signals with each other, to thereby detect the rotor slot in which the short circuit has occurred.

6. The short-circuit detection device according to claim 1, wherein the detection signal is to be acquired from a device different from the short-circuit detection device.

7. A short-circuit detection method for detecting a short circuit of a field winding wound in a plurality of rotor slots in a rotor of a rotating electric machine, the short-circuit detection method comprising:
converting a detection signal in which a circumferential distribution of a magnetic flux of the rotor is detected into an energy equivalent signal corresponding to a circumferential distribution of magnetic energy of the rotor; and
detecting a rotor slot in which the short circuit has occurred through use of the energy equivalent signal.

8. The short-circuit detection device according to claim 2, wherein the short-circuit detection circuitry is configured to compare the energy equivalent signal converted from a current detection signal with the energy equivalent signal converted from a past detection signal, to thereby detect the rotor slot in which the short circuit has occurred.

9. The short-circuit detection device according to claim 2, further comprising a signal delaying circuitry configured to generate a delay signal by delaying a phase of the detection signal by 180° in an electrical angle,
wherein the signal conversion circuitry is configured to convert the delay signal into the energy equivalent signal, and
wherein the short-circuit detection circuitry is configured to compare the energy equivalent signal converted from the detection signal with the energy equivalent signal converted from the delay signal, to thereby detect the rotor slot in which the short circuit has occurred.

10. The short-circuit detection device according to claim 2,
wherein the signal conversion circuitry is configured to convert the detection signals detected at respective positions different from each other by a phase of 180° or more in an electrical angle into the energy equivalent signals, and
wherein the short-circuit detection circuitry is configured to compare the energy equivalent signals with each other, to thereby detect the rotor slot in which the short circuit has occurred.

11. The short-circuit detection device according to claim 2, wherein the detection signal is to be acquired from a device different from the short-circuit detection device.

12. The short-circuit detection device according to claim 3, wherein the detection signal is to be acquired from a device different from the short-circuit detection device.

13. The short-circuit detection device according to claim 4, wherein the detection signal is to be acquired from a device different from the short-circuit detection device.

14. The short-circuit detection device according to claim 5, wherein the detection signal is to be acquired from a device different from the short-circuit detection device.

15. The short-circuit detection device according to claim 8, wherein the detection signal is to be acquired from a device different from the short-circuit detection device.

16. The short-circuit detection device according to claim 9, wherein the detection signal is to be acquired from a device different from the short-circuit detection device.

17. The short-circuit detection device according to claim 10, wherein the detection signal is to be acquired from a device different from the short-circuit detection device.
